(19) United States
(12) Patent Application Publication
(10) Pub. No.: US 2025/0210327 A1
(43) Pub. Date: Jun. 26, 2025

(54) PLASMA PROCESSING METHOD AND PLASMA PROCESSING APPARATUS

(71) Applicant: Tokyo Electron Limited, Tokyo (JP)

(72) Inventor: Takahiro YONEZAWA, Miyagi (JP)

(73) Assignee: Tokyo Electron Limited, Tokyo (JP)

(21) Appl. No.: 19/065,059

(22) Filed: Feb. 27, 2025

Related U.S. Application Data
(63) Continuation of application No. PCT/JP2023/031083, filed on Aug. 29, 2023.

(30) Foreign Application Priority Data
Aug. 30, 2022 (JP) 2022-136874

(51) Int. Cl. H01J 37/32; H01L 21/311

(52) U.S. Cl. CPC H01J 37/32724; H01J 37/32128; H01J 37/32449; H01J 37/32816; H01L 21/31116; H01L 21/31144; H01J 2237/332; H01J 2237/334

(57) ABSTRACT

A plasma processing method executed in a plasma processing apparatus, including a chamber and a substrate support provided in the chamber, the method including (a) preparing a substrate including a silicon-containing film and a mask film on the silicon-containing film, which is an inorganic film containing silicon, and the mask film including an opening pattern; and (b) forming plasma in the chamber and etching the silicon-containing film through the mask film to form a concave portion in the silicon-containing film, the (b) including (b-1) supplying a processing gas containing hydrogen fluoride into the chamber, (b-2) forming plasma from the processing gas in the chamber, and (b-3) supplying a bias signal to the substrate support, the bias signal being a bias RF signal or a bias DC signal including a sequence of negatively-polarized DC pulses.

### CROSS-REFERENCE TO RELATED APPLICATIONS

This application is a Continuation of International Patent Application No. PCT/JP2023/031083, filed on Aug. 29, 2023, which claims priority from Japanese Patent Application No. 2022-136874, filed on Aug. 30, 2022, the entire contents of each are incorporated herein by reference.

### BACKGROUND

### Field

Exemplary embodiments of the present disclosure relate to a plasma processing method and a plasma processing apparatus.

### Description of Related Art

In the manufacturing of an electronic device, plasma etching of a silicon-containing film of a substrate is performed. For example, JP 2016-39309 A discloses a method of etching a dielectric film by plasma etching.

### SUMMARY

In one exemplary embodiment of the present disclosure, there is provided a plasma processing method executed in a plasma processing apparatus, in which the plasma processing apparatus includes a chamber and a substrate support provided in the chamber, the plasma processing method including: (a) preparing a substrate on the substrate support, the substrate including a silicon-containing film and a mask film on the silicon-containing film, the silicon-containing film being an inorganic film containing silicon, and the mask film including an opening pattern having an opening width of 30 nm or less; and (b) forming plasma in the chamber and etching the silicon-containing film through the mask film to form a concave portion in the silicon-containing film, in which the (b) includes (b-1) supplying a processing gas containing hydrogen fluoride into the chamber, (b-2) forming plasma from the processing gas in the chamber, and (b-3) supplying a bias signal to the substrate support, an effective value of power included in the bias signal being 2 kW or less.

### BRIEF DESCRIPTION OF DRAWINGS

FIG. 1 is a diagram for describing a configuration example of a plasma processing system.

FIG. 2 is a diagram for describing a configuration example of a plasma processing apparatus.

FIG. 3 is a flowchart illustrating an example of the present processing method.

FIG. 4A is a diagram illustrating an example of a cross-sectional structure of a substrate W.

FIG. 4B is a diagram illustrating an example of a cross-sectional structure of the substrate W.

FIG. 4C is a diagram illustrating an example of a cross-sectional structure of the substrate W.

FIG. 4D is a diagram illustrating an example of a cross-sectional structure of the substrate W.

FIG. 4E is a diagram illustrating an example of a cross-sectional structure of the substrate W.

FIG. 5 is a flowchart illustrating an example of a step ST1.

FIG. 6A is a diagram illustrating an example of a cross-sectional structure of the substrate W.

FIG. 6B is a diagram illustrating an example of a cross-sectional structure of the substrate W.

FIG. 6C is a diagram illustrating an example of a cross-sectional structure of the substrate W.

FIG. 6D is a diagram illustrating an example of a cross-sectional structure of the substrate W.

FIG. 7 is a flowchart illustrating an example of the step ST1.

FIG. 8A is a diagram illustrating an example of a cross-sectional structure of the substrate W.

FIG. 8B is a diagram illustrating an example of a cross-sectional structure of the substrate W.

FIG. 8C is a diagram illustrating an example of a cross-sectional structure of the substrate W.

FIG. 8D is a diagram illustrating an example of a cross-sectional structure of the substrate W.

FIG. 8E is a diagram illustrating an example of a cross-sectional structure of the substrate W.

FIG. 9 is a flowchart illustrating an example of the step ST1.

FIG. 10A is a diagram illustrating an example of a cross-sectional structure of the substrate W.

FIG. 10B is a diagram illustrating an example of a cross-sectional structure of the substrate W.

FIG. 10C is a diagram illustrating an example of a cross-sectional structure of the substrate W.

FIG. 11 is a flowchart illustrating an example of a step ST23.

FIG. 12A is a diagram illustrating an example of a cross-sectional structure of the substrate W in the step ST23.

FIG. 12B is a diagram illustrating an example of a cross-sectional structure of the substrate W in the step ST23.

### DETAILED DESCRIPTION

Hereinafter, each embodiment of the present disclosure will be described.

In one exemplary embodiment, a plasma processing method executed in a plasma processing apparatus is provided. A plasma processing apparatus includes a chamber, and a substrate support provided in the chamber, and a plasma processing method includes (a) preparing a substrate on the substrate support, the substrate including a silicon-containing film and a mask film on the silicon-containing film, the silicon-containing film being an inorganic film containing silicon, and the mask film including an opening pattern having an opening width of 30 nm or less; and (b) forming plasma in the chamber and etching the silicon-containing film through the mask film to form a concave portion in the silicon-containing film, in which the (b) includes (b-1) supplying a processing gas containing hydrogen fluoride into the chamber, (b-2) forming plasma from the processing gas in the chamber, and (b-3) supplying a bias signal to the substrate support, the bias signal being a bias RF signal having an effective value of power of less than 2 kW or a bias DC signal including a sequence of negatively-polarized DC pulses having an effective value of a voltage of less than 2 kV.

In one exemplary embodiment, the substrate support includes a plurality of zones in a substrate support surface that supports the substrate, the (a) includes setting a temperature of the substrate support in units of the zones, and in the (b), the silicon-containing film is etched in a state where the temperature of the substrate support is set in units of the zones.

In one exemplary embodiment, the substrate support includes a temperature control module configured to control a temperature of the substrate, the temperature control module including one or a plurality of heaters, and the (b) is executed in a state where a temperature of the substrate support is set to 80° C. or less by the temperature control module.

In one exemplary embodiment, the processing gas further includes at least one selected from the group consisting of a carbon-containing gas, a phosphorus-containing gas, a metal-containing gas, a boron-containing gas, an oxygen-containing gas, and a halogen-containing gas.

In one exemplary embodiment, the processing gas includes a phosphorus-containing gas.

In one exemplary embodiment, the processing gas includes at least one inert gas selected from the group consisting of a noble gas and a nitrogen gas.

In one exemplary embodiment, a proportion of flow rates of the hydrogen fluoride gas and the inert gas to a total flow rate of the processing gas is 50 vol % or more.

In one exemplary embodiment, a ratio of the flow rate of the inert gas to the flow rate of the hydrogen fluoride gas is 0.1 or more and 200 or less.

In one exemplary embodiment, the plasma processing apparatus has a first gas injector that is disposed on an upper surface of the chamber to face the substrate support, and a second gas injector that is disposed on a side surface of the chamber, the processing gas includes at least one first gas that does not contain carbon and at least one second gas that contains carbon, at least one of the first gas is supplied from the first gas injector, and at least one of the second gas is supplied from the second gas injector.

In one exemplary embodiment, the plasma processing apparatus has a first gas injector disposed on an upper surface of the chamber in the chamber, and a second gas injector disposed on a side surface of the chamber in the chamber, the processing gas includes at least one of carbon-containing gas, the at least one of carbon-containing gas is supplied into the chamber from the first gas injector and the second gas injector, and a flow rate of the at least one of carbon-containing gas supplied into the chamber from the second gas injector is higher than a flow rate of the at least one of carbon-containing gas supplied into the chamber from the first gas injector.

In one exemplary embodiment, in the (b), a pressure in the chamber is set to 50 mTorr or less.

In one exemplary embodiment, the mask film includes a resist film.

In one exemplary embodiment, the mask film includes an EUV resist film.

In one exemplary embodiment, the resist film includes a metal-containing resist.

In one exemplary embodiment, a thickness of the silicon-containing film is 40 nm or less.

In one exemplary embodiment, an aspect ratio of the concave portion formed in the silicon-containing film is 5 or less.

In one exemplary embodiment, the (a) includes (a-1) preparing a substrate including the silicon-containing film, an antireflection film on the silicon-containing film, and the mask film on the antireflection film, and (a-2) removing a portion of the antireflection film exposed from the opening pattern and a part of the mask film using plasma formed from a first processing gas containing oxygen.

In one exemplary embodiment, further including: (a-3) forming, after the (a-2), at least one of a deposit selected from the group consisting of carbon, silicon, and a metal on a first region and a second region of the mask film by using a second processing gas, the first region including an upper surface of the mask film, the second region including a side surface of the mask film, and the side surface defining the opening pattern; and (a-4) removing at least a part of the deposit on the second region and a portion of the antireflection film exposed from the opening pattern by using plasma formed from a third processing gas containing oxygen.

In one exemplary embodiment, the (a) includes (a-1) preparing a substrate including the silicon-containing film, an antireflection film on the silicon-containing film, and a mask film on the antireflection film, (a-3) forming, after the (a-1), at least one of a deposit selected from the group consisting of carbon, silicon, and a metal on a first region and a second region of the mask film by using a second processing gas, the first region including an upper surface of the mask film, the second region including a side surface of the mask film, and the side surface defining the opening pattern, and (a-4) removing at least a part of the deposit on the second region and a portion of the antireflection film exposed from the opening pattern by using a third processing gas.

In one exemplary embodiment, a plasma processing method executed in a plasma processing apparatus is provided. A plasma processing apparatus includes a chamber, and a substrate support provided in the chamber, and a plasma processing method includes (a) preparing a substrate on the substrate support, the substrate including a silicon-containing film and a mask film on the silicon-containing film, the silicon-containing film being an inorganic film containing silicon, and the mask film including an opening pattern; and (b) forming plasma in the chamber and etching the silicon-containing film through the mask film to form a concave portion in the silicon-containing film, in which in the (a), a width of an opening included in the opening pattern is 30 nm or less, and the (b) includes (b-1) supplying a processing gas containing at least hydrogen and fluorine into the chamber, (b-2) forming plasma including a hydrogen fluoride species from the processing gas in the chamber, and (b-3) supplying a bias signal to the substrate support, the bias signal being a bias RF signal having an effective value of power of 2 kW or a bias DC signal including a sequence of negatively-polarized DC pulses having an effective value of a voltage of less than 2 kV.

In one exemplary embodiment, a plasma processing method executed in a plasma processing apparatus is provided. A plasma processing apparatus includes a chamber, and a substrate support provided in the chamber, and a plasma processing method including: (a) preparing a substrate including a first silicon-containing film, a carbon-containing film on the first silicon-containing film, a second silicon-containing film on the carbon-containing film, and a resist film on the second silicon-containing film, and the resist film including an opening pattern having an opening width of 30 nm or less; (b) etching the second silicon-containing film through the resist film and forming a first concave portion on the second silicon-containing film; (c) etching the carbon-containing film through the first concave portion and forming a second concave portion on the carbon-containing film; and (d) etching the first silicon-containing film through the second concave portion, in which in the (b), (c), and (d), a bias signal having an effective value of less than 2 kW is supplied to the substrate support, and the (b) includes (b-1) supplying a processing gas containing at least hydrogen and fluorine, and (b-2) forming plasma containing a hydrogen fluoride species from the processing gas.

In one exemplary embodiment, the substrate further includes an underlying film under the first silicon-containing film, the (d) includes (d-1) etching the first silicon-containing film by using plasma formed from a fourth processing gas containing fluorine and forming a third concave portion on the first silicon-containing film, the third concave portion having an opening dimension on a carbon-containing film side larger than an opening dimension on an underlying film side, and (d-2) enlarging the opening dimension of the third concave portion on the underlying film side by using plasma formed from a fifth processing gas containing a hydrogen fluoride gas and a carbon-containing gas.

In one exemplary embodiment, the fourth processing gas includes at least one of a hydrogen fluoride gas and a fluorocarbon gas, and the carbon-containing gas includes a hydrofluorocarbon gas having 3 or more carbon atoms.

In one exemplary embodiment, plasma is continuously formed over two or more consecutive of the (b), (c), and (d).

In one exemplary embodiment, the plasma processing apparatus is an inductively coupled plasma processing apparatus, and the (a), (b), (c), and (d) are executed in the same chamber.

In one exemplary embodiment, there is provided a plasma processing apparatus including a chamber, a gas supply, a plasma generator, a substrate support provided in the chamber, and a controller. In the plasma processing apparatus, the controller is configured to execute (a) preparing a substrate on the substrate support, the substrate including a silicon-containing film and a mask film on the silicon-containing film, the silicon-containing film being an inorganic film containing silicon, and the mask film including an opening pattern; and (b) forming plasma in the chamber and etching the silicon-containing film through the mask film to form a concave portion in the silicon-containing film, in which in the (b), the controller is configured to execute (b-1) supplying a processing gas containing hydrogen fluoride into the chamber, (b-2) forming plasma from the processing gas in the chamber, and (b-3) supplying a bias signal to the substrate support, the bias signal being a bias RF signal having an effective value of power of less than 2 kW or a bias DC signal including a sequence of negatively-polarized DC pulses having an effective value of a voltage of less than 2 kV.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing System

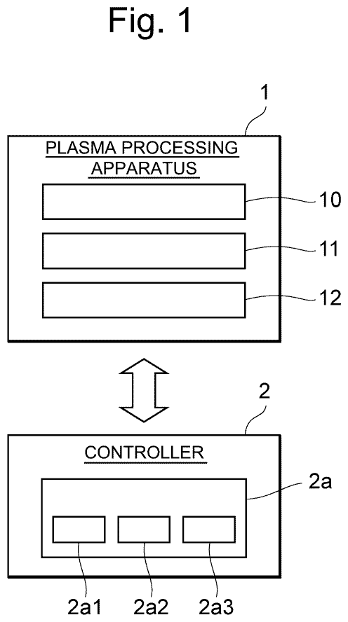

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40, described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHz. Therefore, the AC signal includes a radio frequency (RF) signal and a microwave signal. In an embodiment, an RF signal has a frequency in the range of 100 kHz to 150 MHz.

### Example of Plasma Processing Apparatus

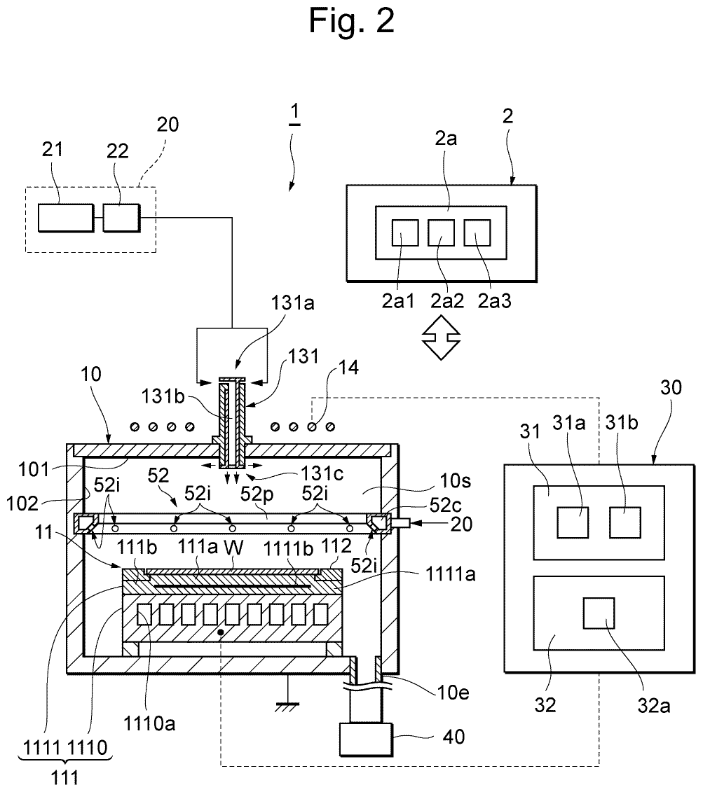

FIG. 2 is a diagram for describing a configuration example of the plasma processing system. The plasma processing system includes the inductively coupled plasma processing apparatus 1 and the controller 2. The inductively coupled plasma processing apparatus 1 includes the plasma processing chamber 10, the gas supply 20, a power supply 30, and the exhaust system 40. The plasma processing chamber 10 includes a dielectric window. In addition, the plasma processing apparatus 1 includes a substrate support 11, a gas introducer, and an antenna 14. The substrate support 11 is disposed in the plasma processing chamber 10. The antenna 14 is disposed on or above the plasma processing chamber 10 (that is, on or above a dielectric window 101). The plasma processing chamber 10 has a plasma processing space 10s defined by the dielectric window 101, a side wall 102 of the plasma processing chamber 10, and the substrate support 11. The plasma processing chamber 10 has at least one gas supply port for supplying at least one processing gas to the plasma processing space 10s, and at least one gas exhaust port for exhausting the gas from the plasma processing space. The plasma processing chamber 10 is grounded.

The substrate support 11 includes a main body 111 and a ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32, which will be described later, may be disposed in the ceramic member 1111a. In this case, at least one RF/DC electrode functions as the bias electrode. The conductive member of the base 1110 and at least one RF/DC electrode may function as a plurality of bias electrodes. Further, the electrostatic electrode 1111b may function as the bias electrode. Therefore, the substrate support 11 includes at least one bias electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The gas introducer is configured to introduce at least one processing gas from the gas supply 20 into the plasma processing space 10s. In an embodiment, the gas introducer includes a center gas injector (CGI) 131. The center gas injector 131 is disposed above the substrate support 11 and is attached to a center opening portion formed in the dielectric window 101. The center gas injector 131 has at least one gas supply port 131a, at least one gas flow passage 131b, and at least one gas introduction port 131c. The processing gas supplied to the gas supply port 131a passes through the gas flow passage 131b and is introduced into the plasma processing space 10s from the gas introduction port 131c. In addition, the gas introducer may include one or a plurality of side gas injectors (SGI: side gas injector) attached to one or a plurality of opening portions formed in the side wall 102 in addition to or instead of the center gas injector 131.

The gas introducer may include a peripheral gas injector 52 as an example of the side gas injector. The peripheral gas injector 52 includes a plurality of peripheral injection ports 52i. The plurality of peripheral injection ports 52i mainly supply gas toward an edge portion of the substrate W. The plurality of peripheral injection ports 52i are open toward the edge portion of the substrate W or an edge portion of the center region 111a that supports the substrate W. The plurality of peripheral injection ports 52i may be disposed at a height position similar to that of the gas introduction port 131c. In addition, the plurality of peripheral injection ports 52i may be disposed below the gas introduction port 131c and above the substrate support 11 along a peripheral direction of the substrate support 11. That is, the plurality of peripheral injection ports 52i are arranged in an annular shape with respect to an axis of the gas flow passage 131b in a region (plasma diffusion region) having a lower electron temperature than directly below the dielectric window 101.

The gas supply 20 may include at least one gas source 21 and at least one flow rate controller 22. In one embodiment, the gas supply 20 is configured to supply at least one processing gas from the gas sources 21 each corresponding thereto to the gas introducer via the flow rate controllers 22 each corresponding thereto. Each flow rate controller 22 may include, for example, a mass flow controller or a pressure-controlled flow rate controller. Further, the gas supply 20 may include one or more flow rate modulation devices that modulate or pulse the flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. As a result, plasma is formed from at least one processing gas supplied to the plasma processing space 10s. Therefore, the RF power supply 31 may function as at least a part of the plasma generator configured to form the plasma from one or more processing gases in the plasma processing chamber 10. Further, by supplying the bias RF signal to at least one bias electrode, the bias potential is generated on the substrate W, and ions in the formed plasma can be drawn into the substrate W.

In an embodiment, the RF power supply 31 includes a first RF generator 31a and a second RF generator 31b. The first RF generator 31a is coupled to the antenna 14 and is configured to generate the source RF signal (source RF power) for plasma formation via at least one impedance matching circuit. In an embodiment, the source RF signal has a frequency in a range of 10 MHz to 150 MHz. In an embodiment, the first RF generator 31a may be configured to generate a plurality of source RF signals having different frequencies. The generated one or plurality of source RF signals are supplied to the antenna 14.

The second RF generator 31b is coupled to at least one bias electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or plurality of bias RF signals are supplied to at least one bias electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a bias DC generator 32a. In an embodiment, the bias DC generator 32a is connected to at least one bias electrode and is configured to generate the bias DC signal. The generated bias DC signal is applied to at least one bias electrode.

In various embodiments, the bias DC signal may be pulsed. In this case, a sequence of voltage pulses is applied to at least one bias electrode. The voltage pulse may have a pulse waveform having a rectangular shape, a trapezoidal shape, a triangular shape, or a combination thereof. In an embodiment, the waveform generator for generating the sequence of voltage pulses from the DC signal is connected between the bias DC generator 32a and at least one bias electrode. Therefore, the bias DC generator 32a and the waveform generator configure the voltage pulse generator. The voltage pulse may have a positive polarity or a negative polarity. In addition, the sequence of voltage pulses may include one or a plurality of positively-polarized voltage pulses and one or a plurality of negatively-polarized voltage pulses in one cycle. The bias DC generator 32a may be provided in addition to the RF power supply 31 or may be provided in place of the second RF generator 31b.

The antenna 14 includes one or a plurality of coils. In an embodiment, the antenna 14 may include an outer coil and an inner coil disposed coaxially. In this case, the RF power supply 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil separately.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

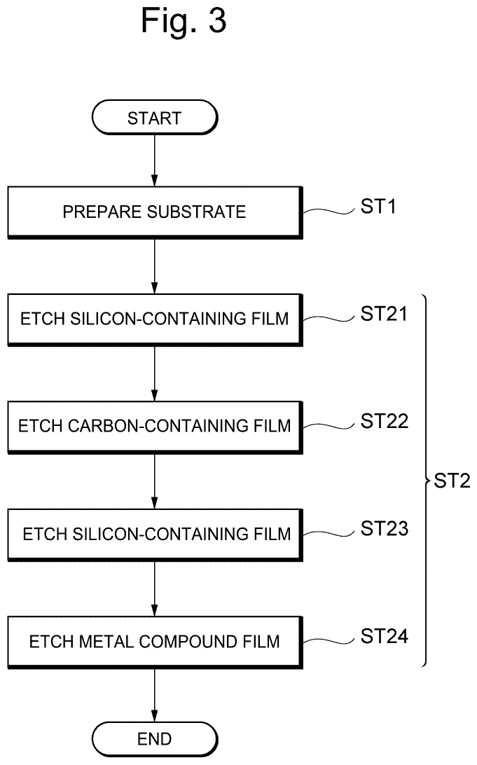

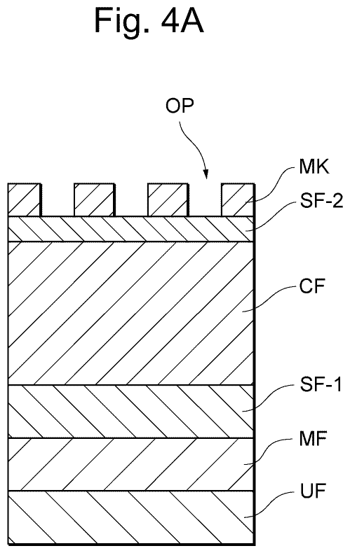

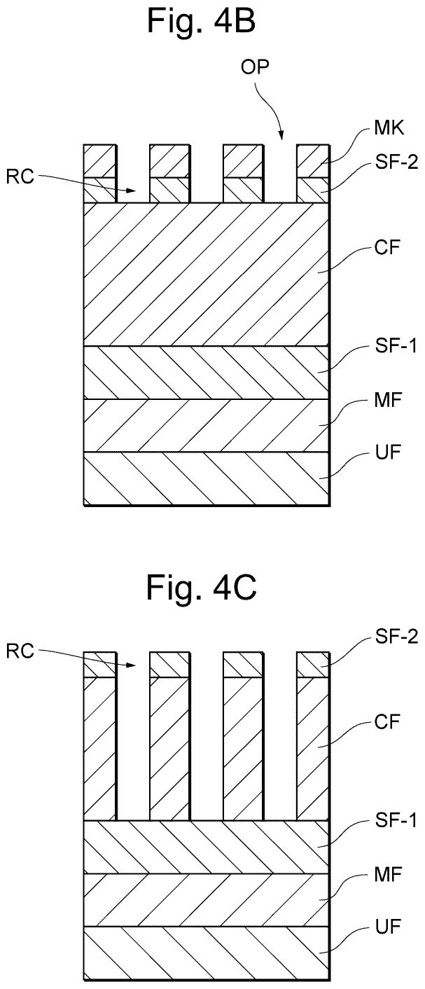

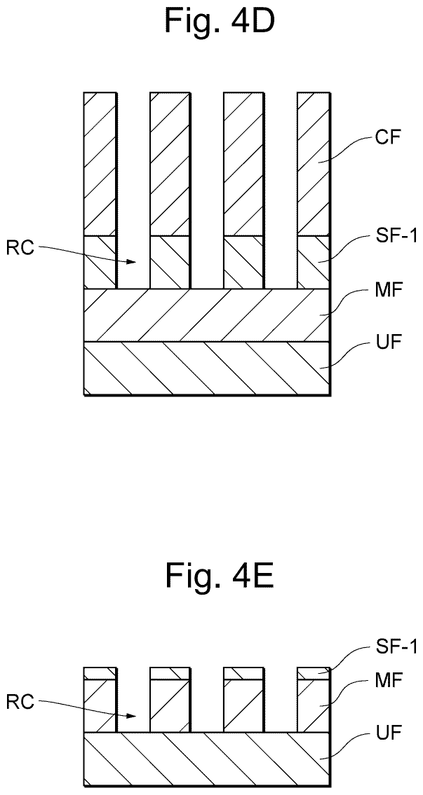

FIG. 3 is a flowchart illustrating an example of a plasma processing method (hereinafter, also referred to as “present processing method”) according to one exemplary embodiment. In addition, FIGS. 4A to 4E are diagrams illustrating an example of a cross-sectional structure of the substrate W. The present processing method is executed on the substrate W using, for example, the plasma processing apparatus 1 illustrated in FIG. 2. Hereinafter, an example of executing the present processing method illustrated in FIG. 3 on the substrate W illustrated in FIG. 4A will be described with reference to each drawing. In the following example, the controller 2 illustrated in FIGS. 1 and 2 controls each unit of the plasma processing apparatus 1 illustrated in FIG. 2, and the present processing method is executed.

### Step ST1: Preparation of Substrate

In the step ST1, the substrate W is prepared in the plasma processing space 10s of the plasma processing chamber 10. In the step ST1, the substrate W is disposed on at least the substrate support 11 and is held by the electrostatic chuck 1111. At least a part of the step of forming each configuration included in the substrate W may be performed in the plasma processing space 10s as a part of the step ST1. In addition, after all or some of each configuration of the substrate W are formed by an external device or a chamber of the plasma processing apparatus 1, the substrate W may be carried into the plasma processing space 10s and disposed on the substrate support 11.

The step ST1 may include a step of setting the temperature of the substrate support 11. In order to set the temperature of the substrate support 11, the controller 2 may control the temperature controlled module. As an example, the controller 2 may set the temperature of the substrate support 11 to 80° C. or lower, 70° C. or lower, or 60° C. or lower. In addition, the substrate support 11 may include a plurality of zones in a plan view of the substrate support surface. Then, the controller 2 may set and control the temperature of the substrate support 11 in each zone unit.

As an example, the substrate W prepared in the plasma processing chamber 10 has a cross-sectional structure illustrated in FIG. 4A. The substrate W includes an underlying film UF, a metal compound film MF, a silicon-containing film SF-1, a carbon-containing film CF, a silicon-containing film SF-2, and a mask film MK. The mask film MK is an example of a mask film and an EUV resist film. The silicon-containing films SF-1 and SF-2 are also collectively referred to as “silicon-containing film SF”.

The underlying film UF may be an organic film, a dielectric film, a metal film, a semiconductor film, or the like formed on a silicon wafer. In addition, the underlying film UF may be a silicon wafer. In addition, the underlying film UF may be configured by stacking a plurality of films.

The metal compound film MF is a film containing a metal or a semiconductor. As an example, the metal compound MF may be a polycrystalline silicon film, a titanium nitride (TiN) film, a tungsten carbide (WC) film, or a tungsten silicide (WSi) film.

The silicon-containing films SF-1 and SF-2 may be films containing silicon (Si). The silicon-containing films SF-1 and SF-2 may be inorganic films containing silicon. The silicon-containing film SF may include a silicon oxide film or a silicon nitride film. As an example, the silicon-containing film is a SiO₂ film or a SiON film. The silicon-containing film may be a film having another film type as long as it is a film containing silicon. In addition, the silicon-containing film SF may include a silicon film (for example, an amorphous silicon film or a polycrystalline silicon film). In addition, the silicon-containing film SF may include at least one of a silicon nitride film, a polycrystalline silicon film, a carbon-containing silicon film, or a low dielectric constant film. The carbon-containing silicon film may include a SiC film and/or an SiOC film. The low dielectric constant film contains silicon and may be used as an interlayer insulating film. In addition, the silicon-containing film SF may be a spin-on-glass (SOG) film or a silicon-containing antireflection (SiARC) film. In addition, the silicon-containing film SF-1 may contain a semimetal and/or a metal. As an example, the silicon-containing film SF-1 may be a SiO₂ film, a boronized silicon film (BSi), a tungsten silicon film (WSi), or a SiN film. In addition, as an example, the silicon-containing film SF-2 may be an SOG film, a SiON film, a SiC film, a SiOC film, or an amorphous silicon film.

In addition, the silicon-containing film SF may include two or more silicon-containing films having different types of films. The two or more silicon-containing films may include a silicon oxide film and a silicon nitride film. The silicon-containing film SF may be, for example, a multilayer film including one or more silicon oxide films and one or more silicon nitride films which are alternately stacked. The silicon-containing film SF may be a multilayer film including a plurality of silicon oxide films and a plurality of silicon nitride films which are alternately stacked. Alternatively, the two or more silicon-containing films may include a silicon oxide film and a silicon film. The silicon-containing film SF may be, for example, a multilayer film including one or more silicon oxide films and one or more silicon films which are alternately stacked. The silicon-containing film SF may be a multilayer film including a plurality of silicon oxide films and a plurality of polycrystalline silicon films which are alternately stacked. Alternatively, the two or more silicon-containing films may include a silicon oxide film, a silicon nitride film, and a silicon film.

In addition, the silicon-containing film SF-1 may be a film having higher etching resistance than the silicon-containing film SF-2. The etching resistance may be, for example, a resistance in etching using a fluorocarbon gas and/or a hydrofluorocarbon gas as a processing gas. The silicon-containing film SF-2 may be thinner than the silicon-containing film SF-1. In addition, the silicon-containing film SF-2 may be thinner than the mask film MK and/or the carbon-containing film CF.

The carbon-containing film CF may be a film containing carbon. The carbon-containing film CF may be a film containing an organic material or a film containing an inorganic material. As an example, the carbon-containing film CF is a spin-on carbon (SOC film) or an amorphous carbon (ACL) film.

The mask film MK may be a metal-containing film. The metal-containing film may be a tin-containing film. The mask film MK is formed from a material having an etching rate lower than the etching rate of the silicon-containing film SF-2 in the step ST2. The mask film MK may be a resist film or a photoresist film for EUV. As an example, the photoresist film for EUV may be a tin-containing film. As an example, the tin-containing film may contain tin oxide and/or tin hydroxide. In addition, as an example, the photoresist film for EUV may be a metal-containing film containing at least one metal selected from the group consisting of iodine (I), tellurium (Te), antimony (Sb), indium (In), silver (Ag), titanium (Ti), chromium (Cr), cobalt (Co), nickel (Ni), copper (Cu), zinc (Zn), germanium (Ge), arsenic (As), and hafnium (Hf).

The mask film MK has an opening pattern that defines at least one opening OP on the silicon-containing film SF-2. The mask film MK has at least one side wall other than an outer periphery of the mask film MK. The opening OP is a closed space defined by the side wall. At least one opening OP defined by the mask film MK may have any shape in plan view of the substrate W. The shape may include a circular shape, an elliptical shape, a rectangular shape, a linear shape, and the like. The opening pattern of the mask film MK may include an array pattern in which a plurality of openings OP having a hole shape are regularly disposed in plan view of the substrate W. The hole shape may include a circular shape, an elliptical shape, a rectangular shape, and the like. In addition, the opening pattern of the mask film MK may include a line-and-space (L/S) pattern in which a plurality of opening OP having a linear shape are arranged at regular intervals in plan view of the substrate W. The pitch of the openings OP (the distance between the centers of the mask films MK) may be 100 nm or less. Alternatively, the width of the opening OP may be 30 nm or less. In a case where the opening OP has the hole shape, the width may be a diameter of the hole. In addition, in a case where the opening pattern has the line-and-space pattern, the width may be a width of the line or the space. In addition, the thickness of the silicon-containing film SF-1 or SF-2 may be 40 nm or less or 20 nm or less.

In the opening OP defined by the mask film MK, the surface (upper surface) of the silicon-containing film SF-2 is exposed. In the step ST2 described later, the silicon-containing film SF-2, the carbon-containing film CF, the silicon-containing film SF-1, and the metal compound film MF are etched based on the shape of the opening OP defined by the mask film MK. Then, a concave portion RC such as a hole or a trench is formed in each film. Each of the one or more concave portions RC formed in each film has a shape based on each of one or more openings OP in plan view of the substrate W.

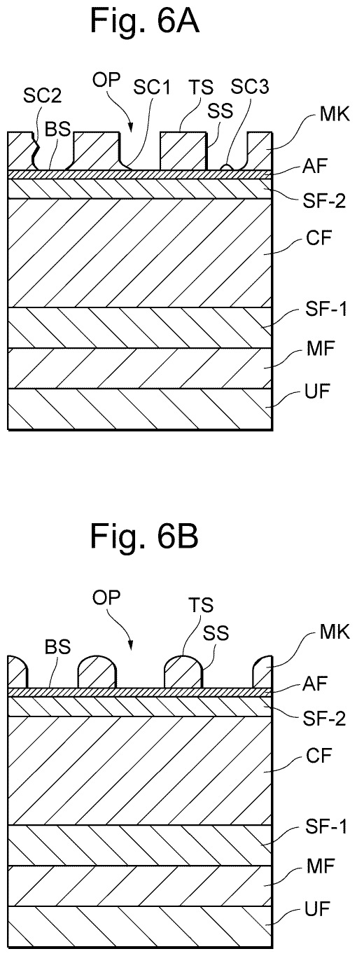

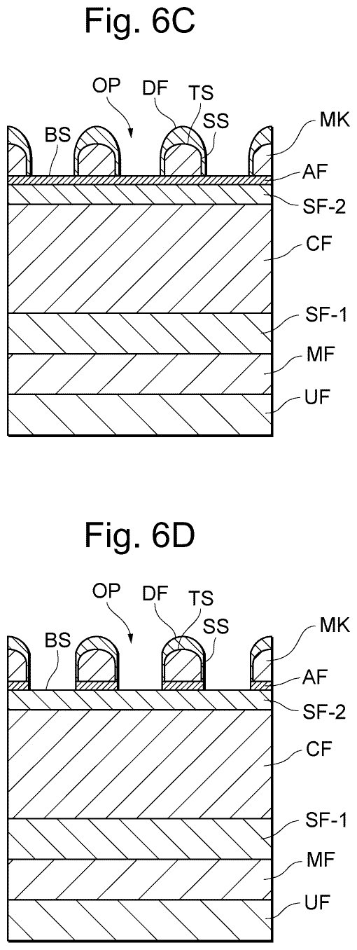

The opening pattern included in the mask film MK may include defects. As an example, the defect of the opening pattern may include an etching residue generated when the opening pattern is formed on the mask film MK. The etching residue may be present on a side wall of the mask film MK defining the opening OP or on a bottom portion of the opening OP (that is, a surface of the silicon-containing film SF-2) (for example, see FIG. 6A).

The substrate W may further include a film containing at least one of carbon or a metal between the mask film MK and the silicon-containing film SF-2. In an embodiment, the film may be a film that functions as an antireflection film.

### Step ST2: Execution of Etching

In the step ST2, each film disposed below the mask film MK on the substrate W is etched. The step ST2 includes a step of etching the silicon-containing film SF-2 (step ST21), a step of etching the carbon-containing film CF (step ST22), a step of etching the silicon-containing film SF-1 (step ST23), and a step of etching the metal compound film MF (step ST24).

Each step of the step ST2 may include a step of supplying the processing gas into the plasma processing chamber 10, a step of supplying the source RF signal, and a step of supplying the bias RF signal. In each step, active species (ions and radicals) of plasma are generated from the processing gas, and each film is etched by the active species. The order in which the supply of the processing gas, the source RF signal, and the bias signal is started is optional. The bias signal supplied in each step of the step ST2 may be a bias RF signal or a bias DC signal. In a case where the bias signal supplied in each step of the step ST2 is the bias RF signal, an effective value (hereinafter, also referred to as “power”) of the power of the bias RF signal may be less than 2 kW or less than 1 kW. In a case where the bias signal supplied in each step of the step ST2 is the bias DC signal, an effective value (hereinafter, also referred to as a “voltage”) of the voltage of the bias DC signal may be less than 2 kV or less than 1 kV. The bias DC signal is a signal including one or more sequences of DC pulses. The voltage of the DC pulse may have a negative polarity. The plasma may be continuously formed in the plasma processing chamber 10 over two or more consecutive steps in the step ST2. That is, the plasma may be formed between two or more consecutive steps without being interrupted. As a result, it is possible to reduce particles generated in the plasma processing chamber 10.

In each step of the step ST2, the processing gas is supplied into the plasma processing chamber 10. The type of the processing gas may be appropriately selected based on the material of the film to be etched in each step, the thickness of the film, the material of the film present above and/or below the film, the pattern of the film serving as a mask, and the like.

In each step of the step ST2, the pressure in the plasma processing chamber 10 may be appropriately set. As an example, the pressure in the plasma processing chamber 10 may be set to 50 mTorr or less, 30 mTorr or less, or 10 mTorr or less.

### Step ST21: Etching of Silicon-Containing Film SF-2

Next, as illustrated in FIG. 4B, in the step ST21, the silicon-containing film SF-2 is etched. As an example, the silicon-containing film SF-2 may be etched using plasma formed from the processing gas including fluorocarbon gas and/or hydrofluorocarbon gas. When the substrate W is etched using the plasma formed from the processing gas in the step ST21, the silicon-containing film SF-2 is etched using the mask film MK as a mask, and the concave portion RC is formed in the silicon-containing film SF-2. The concave portion RC formed in the silicon-containing film SF-2 is an example of a first concave portion. In addition, the carbon-containing film CF is exposed at the bottom portion of the concave portion RC. In the etching of the silicon-containing film SF-2, a part of the mask film MK may be etched. In addition, in a case where the opening pattern of the mask film MK includes defects including the etching residues, the silicon-containing film SF-2 may be etched using the etching residues as the mask. That is, the pattern formed in the silicon-containing film SF-2 by the concave portion RC may also include defects based on the etching residues.

### Step ST22: Etching of Carbon-Containing Film CF

Next, as illustrated in FIG. 4C, in the step ST22, the carbon-containing film CF is etched. As an example, the carbon-containing film CF may be etched using plasma formed from the processing gas containing hydrogen, halogen, and oxygen. In addition, as an example, the processing gas may contain one or more gases consisting of molecules containing hydrogen, bromine, chlorine, and/or iodine. As an example, the gas is H₂, Br₂, Cl₂, HBr, HCl, HI, or the like. The processing gas may include one or more gases consisting of molecules containing oxygen. As an example, the gas is O₂, CO₂, COS, or the like. In addition, the processing gas may include an inert gas such as He, Ar, or N₂.

As an example, in a case where the mask film MK is a tin-containing film, when the substrate W is etched using the plasma formed from the processing gas in the step ST22, the mask film MK is removed as illustrated in FIG. 4C. Then, the carbon-containing film CF is etched using the silicon-containing film SF-2 as the mask, and the concave portion RC is formed in the carbon-containing film CF. The concave portion RC formed in the carbon-containing film CF is an example of a second concave portion. In addition, the silicon-containing film SF-1 is exposed at the bottom portion of the concave portion RC. In the etching of the carbon-containing film CF, a part of the silicon-containing film SF-2 may be etched. In addition, in a case where the opening pattern of the mask film MK includes defects including the etching residues, the carbon-containing film CF may be etched using the silicon-containing film SF-2 including defects based on the etching residues as the mask. That is, the pattern formed in the carbon-containing film CF by the concave portion RC may also include defects based on the etching residues.

### Step ST23: Etching of Silicon-Containing Film SF-1

Next, as illustrated in FIG. 4D, in the step ST23, the silicon-containing film SF-1 is etched. As an example, the silicon-containing film SF-1 may be etched using plasma formed from the processing gas containing one or more gases containing carbon, hydrogen, and fluorine. The processing gas includes one or more gases. Here, each of the one or more gases may contain hydrogen, carbon, and fluorine. In addition, in a case where the one or more gases are a plurality of gases, one gas among the plurality of gases may include one or more of hydrogen, carbon, and fluorine, and a part or all of the remaining one or more gases among the plurality of gases may include the remaining hydrogen, carbon, and fluorine.

The processing gas used in the step ST23 may include a gas capable of generating a hydrogen fluoride (HF) species in the plasma processing chamber 10 during the plasma processing. The hydrogen fluoride species function as an etchant that etches the silicon-containing film SF-1 in the step ST23.

The gas containing carbon, hydrogen, and fluorine may be at least one gas selected from the group consisting of hydrofluorocarbons. The hydrofluorocarbon is, for example, at least one of CH₂F₂, CHF₃, or CH₃F. The hydrofluorocarbon may contain two or more carbon atoms or may contain two or more and six or less carbon atoms. The hydrofluorocarbon may contain, for example, two carbon atoms such as C₂HF₅, C₂H₂F₄, C₂H₃F₃, and C₂H₄F₂. The hydrofluorocarbon may contain, for example, three or four carbon atoms such as C₃HF₇, C₃H₂F₂, C₃H₂F₄, C₃H₂F₆, C₃H₃F₅, C₄H₂F₆, and C₄H₅F₅, C₄H₂F₈. The hydrofluorocarbon gas may contain, for example, five carbon atoms such as C₅H₂F₆, C₅H₂F₁₀, and C₅H₃F₇. As an embodiment, the hydrofluorocarbon gas includes at least one selected from the group consisting of C₃H₂F₄, C₃H₂F₆, C₄H₂F₆, and C₄H₂F₈. The processing gas may include hydrogen fluoride (HF) as a gas capable of generating hydrogen fluoride (HF) species in the plasma processing chamber 10 during the plasma processing. In the processing gas, a ratio of the number of hydrogen atoms to the number of fluorine atoms may be 0.3 or more, 0.4 or more, or 0.5 or more. In addition, in the processing gas, a ratio of the number of hydrogen atoms to the number of carbon atoms may be 1.0 or more, 1.5 or more, or 2.0 or more.

In addition, the processing gas may include a mixed gas capable of generating the hydrogen fluoride species in the plasma processing chamber 10 during the plasma processing, as a gas containing hydrogen and fluorine. The mixed gas capable of generating the hydrogen fluoride species may include a hydrogen source and a fluorine source. The hydrogen source may be, for example, H₂, NH₃, H₂O, H₂O₂, or hydrocarbon (CH₄, C₃H₆, or the like). The fluorine source may be BF₃, NF₃, PF₃, PF₅, SF₆, WF₆, XeF₂, or fluorocarbon. As an example, the mixed gas capable of generating the hydrogen fluoride species is a mixed gas of nitrogen trifluoride (NF₃) and hydrogen (H₂).

In addition, the processing gas may include at least one carbon-containing gas selected from the group consisting of hydrocarbon (CₓH_{y}) and fluorocarbon (CᵥF_{w}) as a gas containing carbon. Here, each of x, y, v, and w is a natural number. The hydrocarbon may include, for example, CH₄, C₂H₆, C₃H₆, C₃H₈, C₄H₁₀, or the like. The fluorocarbon may include, for example, CF₄, C₂F₂, C₂F₄, C₃F₈, C₄F₆, C₄F₈, C₅F₈, or the like. The chemical species generated from these carbon-containing gases may protect the mask film MK.

The gas containing carbon may be a linear gas having an unsaturated bond. The linear carbon-containing gas having the unsaturated bond may use, for example, at least one selected from the group consisting of hexafluoropropene (C₃F₆) gas, octafluoro-1-butene, octafluoro-2-butene (C₄F₈) gas, 1,3,3,3-tetrafluoropropene (C₃H₂F₄) gas, trans-1,1,1,4,4,4-hexafluoro-2-butene (C₄H₂F₆) gas, pentafluoroethyl trifluorovinyl ether (C₄F₈O) gas, 1,2,2,2-tetrafluoroethane-1-one (CF₃COF gas), difluoroacetic acid fluoride (CHF₂COF) gas, and carbonyl fluoride (COF₂) gas. These gases are gases having a relatively low global warming potential (GWP), and thus are significant for improvement of the greenhouse effect.

In addition, the processing gas may further contain at least one phosphorus-containing molecule. The phosphorus-containing molecule may be an oxide such as tetraphosphorus decaoxide (P₄O₁₀), tetraphosphorus octoxide (P₄O₈), and tetraphosphorus hexaoxide (P₄O₆). Tetraphosphorus decaoxide is sometimes referred to as phosphorus pentoxide (P₂O₅). The phosphorus-containing molecule may be halides (phosphorous halides) such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), and phosphorus iodide (PI₃). That is, the molecule containing phosphorus may be a fluoride (phosphorous fluoride) containing fluorine as a halogen element. Alternatively, the molecule containing phosphorus may contain a halogen element other than fluorine as the halogen element. The phosphorus-containing molecule may be a phosphoryl halide such as phosphoryl fluoride (POF₃), phosphoryl chloride (POCl₃), and phosphoryl bromide (POBr₃). The phosphorus-containing molecule may be phosphine (PH₃), calcium phosphate (CasP₂ and the like), phosphoric acid (H₃PO₄), sodium phosphate (Na₃PO₄), hexafluorophosphoric acid (HPF₆), and the like. The phosphorus-containing molecule may be a fluorophosphine (HₓPF_{y}). Here, the sum of x and y is 3 or 5. As the fluorophosphines, HPF₂ and H₂PF₃ are illustrated. The processing gas may include one or more phosphorus-containing molecules among the above-described phosphorus-containing molecules as at least one phosphorus-containing molecule. For example, the processing gas may include at least one of PF₃, PCl₃, PF₅, PCl₅, POCl₃, PH₃, PBr₃, or PBr₅ as at least one phosphorus-containing molecule. In addition, at least one phosphorus-containing molecule may include at least one selected from the group consisting of PClₐF_{b} (a and b are positive integers) and PC_{c}H_{d}Fₑ (c, d, and e are positive integers). In a case where each phosphorus-containing molecule contained in the processing gas is a liquid or a solid, each phosphorus-containing molecule may be vaporized by heating or the like and supplied into the plasma processing chamber 10.

In addition, the processing gas may include a halogen-containing molecule. The halogen-containing molecule may not contain carbon. The halogen-containing molecule may be a fluorine-containing molecule or may be a halogen-containing molecule containing a halogen element other than fluorine. The fluorine-containing molecule may include, for example, gases such as nitrogen trifluoride (NF₃), sulfur hexafluoride (SF₆), and boron trifluoride (BF₃). The halogen-containing molecule containing a halogen element other than fluorine may be, for example, at least one selected from the group consisting of a chlorine-containing gas, a bromine-containing gas, and iodine. The chlorine-containing gas is, for example, a gas such as chlorine (Cl₂), silicon dichloride (SiCl₂), silicon tetrachloride (SiCl₄), carbon tetrachloride (CCl₄), dichlorosilane (SiH₂Cl₂), silicon hexachloride (Si₂Cl₆), chloroform (CHCl₃), sulfury chloride (SO₂Cl₂), or boron trichloride (BCl₃). The bromine-containing gas is, for example, a gas such as bromine (Br₂), hydrogen bromide (HBr), dibromodifluoromethane (CBr₂F₂), bromopentafluoroethane (C₂F₅Br), phosphorus tribromide (PBr₃), phosphorus pentabromide (PBr₅), oxybromide phosphate (POBr₃), or boron tribromide (BBr₃). The iodine-containing gas is, for example, a gas such as hydrogen iodide (HI), trifluoroiodomethane (CF₃I), pentafluoroiodoethane (C₂F₅I), heptafluoropropyl iodide (C₃F₇I), iodine pentafluoride (IF₅), iodine heptafluoride (IF₇), iodine (I₂), or phosphorus triiodide (PI₃). Chemical species generated from these halogen-containing molecules may be used for controlling the shape of the concave portion formed by the plasma etching.

The processing gas may contain an oxygen-containing molecule. The oxygen-containing molecule may contain, for example, O₂, CO₂, or CO. In addition, the processing gas may include noble gases such as Ar, Kr, and Xe.

In addition, in the plasma processing apparatus 1 of FIG. 2, the processing gas may be supplied into the plasma processing chamber 10 from one or both of the center gas injector 131 and the side gas injector. For example, the flow rate of the carbon-containing gas supplied from the side gas injector may be larger than the flow rate of the carbon-containing gas supplied from the center gas injector 131. That is, the proportion of the flow rate of the carbon-containing gas supplied from the center gas injector 131 to the flow rate of the carbon-containing gas contained in the processing gas may be 50% or less, and the proportion of the flow rate of the carbon-containing gas supplied from the side gas injector to the flow rate of the carbon-containing gas contained in the processing gas may be 50% or more. In addition, the proportion of the flow rate of the carbon-containing gas supplied from the center gas injector 131 to the flow rate of the carbon-containing gas included in the processing gas may be 20% or less, and the proportion of the flow rate of the carbon-containing gas supplied from the side gas injector to the flow rate of the carbon-containing gas included in the processing gas may be 80% or more. In addition, the proportion of the flow rate of the carbon-containing gas supplied from the center gas injector 131 to the flow rate of the carbon-containing gas included in the processing gas may be 10% or less, and the proportion of the flow rate of the carbon-containing gas supplied from the side gas injector to the flow rate of the carbon-containing gas included in the processing gas may be 90% or more. In addition, the proportion of the flow rate of the carbon-containing gas supplied from the center gas injector 131 to the flow rate of the carbon-containing gas included in the processing gas may be 5% or less, and the proportion of the flow rate of the carbon-containing gas supplied from the side gas injector to the flow rate of the carbon-containing gas included in the processing gas may be 95% or more. In addition, the proportion of the flow rate of the carbon-containing gas supplied from the side gas injector to the flow rate of the carbon-containing gas included in the processing gas may be 100%.

In addition, as an example, in the processing gas supplied into the plasma processing chamber 10, the number of carbon atoms contained in the carbon-containing gas supplied from the side gas injector may be larger than the number of carbon atoms contained in the carbon-containing gas supplied from the center gas injector 131.

By supplying at least a part of the carbon-containing gas included in the processing gas from the side gas injector into the plasma processing chamber 10, it is possible to improve the uniformity of the etching rate of the etching film and/or the uniformity of the dimensions of the concave portions formed in the etching film in the plane of the substrate W.

Next, the source RF signal and the bias signal supplied in the step ST23 will be described. The source RF signal supplied in the step ST23 may be supplied to, for example, the upper electrode in the plasma processing apparatus 1 in FIG. 2 or the antenna 14 of the plasma processing apparatus 1 in FIG. 2. The upper electrode is an example of an electrode. The source RF signal may be a continuous wave of RF or a pulse wave. The power of the source RF signal is larger than the power of the bias signal. For example, the power of the source RF signal may be 300 W or more. In addition, the power of the source RF signal may be 500 W or more, 1,000 W or more, or 2,000 W or more.

The bias signal supplied in the step ST23 is supplied to the substrate support 11 in FIG. 2 as an example. The bias signal may be supplied to a member that may function as the bias electrode in the substrate support 11. The bias signal may be the RF signal. The power of the bias signal is smaller than the power of the source RF signal. As an example, the power of the bias signal may be 200 W or less. In addition, the power of the bias signal may be 100 W or less or 50 W or less. As an example, the power of the bias signal may be larger than the power of the source RF signal.

When the substrate W is etched using the plasma formed from the processing gas in the step ST23, the silicon-containing film SF-1 is etched using the silicon-containing film SF-2 and/or the carbon-containing film CF as the mask, and the concave portion RC is formed in the silicon-containing film SF-1. The concave portion RC formed in the silicon-containing film SF-1 is an example of a third concave portion. In addition, the metal compound MF is exposed at the bottom portion of the concave portion RC. The silicon-containing film SF-2 may be etched under the same etching conditions as those for the silicon-containing film SF-1. The etching conditions may include the type of the processing gas, the power of the source RF signal, the power of the bias signal, and the pressure in the plasma processing chamber 10.

In the step ST23, the deposit containing a metal, which is generated in the step ST21 and/or the step ST22, may be removed. The metal may be a metal contained in the mask film MK. In addition, as an example, the metal may be tin (Sn). The deposit may be a residue of a compound or the like containing the metal, which is generated in the etching of the step ST21 and/or the step ST22. In addition, the deposit may be a deposit attached to the substrate W, or may be a deposit attached to the inner wall of the plasma processing chamber 10.

### Other Examples of Step ST1

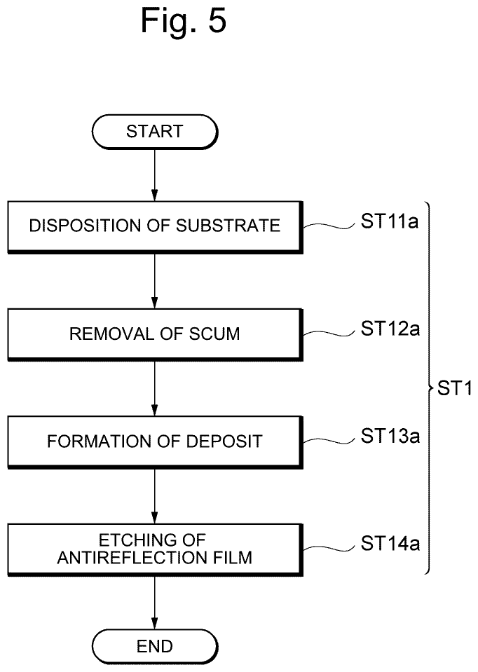

FIG. 5 is a flowchart illustrating an example of the step (ST1) of preparing the substrate. In the present example, the step ST1 includes a step of disposing the substrate (ST11a), a step of removing scum (ST12a), a step of forming the deposit (ST13a), and a step of etching the antireflection film (ST14a). FIGS. 6A to 6D are diagrams illustrating an example of a cross-sectional structure of the substrate W in the step ST1. In each step illustrated in FIG. 5, at least one of the one or two or more gases exemplified in each step illustrated in FIG. 3 may be used.

First, in the step ST11a, the substrate W is disposed on the substrate support 11. FIG. 6A illustrates an example of a cross-sectional structure of the substrate W disposed on the substrate support 11. In the example illustrated in FIG. 6A, the substrate W further includes an antireflection film AF on the silicon-containing film SF-2. That is, the substrate W further includes the antireflection film AF between the silicon-containing film SF-2 and the mask film MK. In the step ST11a, after the substrate W is disposed on the substrate support 11, the opening pattern including the opening OP may be formed in the mask film MK. The opening pattern may be formed by dry-etching or dry-developing the mask film MK.

The antireflection film AF may be a film containing at least one of carbon or a metal. In an embodiment, the antireflection film AF may be the carbon-containing film or the metal-containing film.

In the example illustrated in FIG. 6A, at least a part of the side surface SS of the mask film MK may have a portion SC extending toward the opening OP. The portion SC may be, for example, a portion SC1 that is present at an outer edge of a bottom surface BS of the opening OP. In addition, the portion SC may be a convex portion SC2 that protrudes from the side surface SS toward the opening OP in a region of the side surface SS that is separated from the bottom surface BS upward. The portion SC (SC1 and SC2) may be scum of the mask film MK. The scum may be, for example, a residue of a resist that is not completely removed in a process (for example, a development process) of forming the opening OP in the mask film MF. The scum of the mask film MK may include, for example, a scum SC3 that is isolated on the bottom surface BS of the opening OP without being connected to the side surface SS of the mask film MK, in addition to the scum constituting the portion SC described above. In addition, the scum of the mask film MK may include a scum (not illustrated) that extends to cross the opening OP or to be bridged between the side surfaces SS. The side surface SS of the mask film MK may have a concave portion (not illustrated) such as a recess or a crack (including a discontinuity of a pattern such as a line pattern).

Next, in the step ST12a, the scum is removed. In the step ST12a, the scum may be removed by the plasma formed from the first processing gas. In an embodiment, the first processing gas may include a gas containing oxygen. As an example, the gas containing oxygen may be at least one selected from the group consisting of oxygen gas (O₂), carbon monoxide gas (CO), carbon dioxide gas (CO₂), carbonyl fluoride gas (COF₂), carbonyl sulfide gas (COS), and phosphoryl chloride (POCl₃).

FIG. 6B is a diagram illustrating an example of a cross-sectional structure of the substrate W after the execution of the step ST12a. As illustrated in FIG. 6B, the portion SC, which is the scum of the mask film MK, is removed in the step ST12a. In addition, a part of the upper surface TS and/or the side surface SS of the mask film MK may also be etched. The opening width of the opening OP after the execution of the step ST12a may be larger than the opening width of the opening OP before the execution of the step ST12a.

Next, in the step ST13a, the deposit is formed. FIG. 6C is a diagram illustrating an example of a cross-sectional structure of the substrate W after the execution of the step ST13a. In the step ST13a, the deposit DF may be formed on the mask film MK as illustrated in FIG. 6C. The deposit DF may be formed thicker on the upper surface TS than on the side surface SS of the mask film MK. In addition, the deposit DF may not be formed on the bottom surface BS (that is, the surface of the antireflection film AF) of the opening OP. The upper surface TS of the mask film MK is an example of a surface included in the first region. The side surface SS is an example of a surface included in the second region.

In the step ST13a, the deposit DF may contain at least one selected from the group consisting of carbon, silicon, and a metal. In an embodiment, the deposit DF may be a carbon-containing film, a silicon-containing film, or a metal-containing film. The deposit DF may be formed by the plasma formed from the second processing gas. The second processing gas may include a gas containing at least one selected from the group consisting of carbon, silicon, and a metal. In an embodiment, the second processing gas may include a gas containing carbon and hydrogen, a gas containing silicon and halogen, and/or a gas containing a metal and halogen.

Next, in the step ST14a, the antireflection film AF is etched. In the step ST14a, the antireflection film AF may be etched by plasma formed from the third processing gas. In an embodiment, the third processing gas may include a gas containing oxygen and/or a gas containing halogen. As an example, in a case where the antireflection film AF is the carbon-containing film, the third processing gas may include at least one selected from the group consisting of an oxygen gas (O₂), a carbon monoxide gas (CO), a carbon dioxide gas (CO₂), a carbonyl fluoride gas (COF₂), a carbonyl sulfide gas (COS), and a phosphoryl chloride (POCl₃). As an example, in a case where the antireflection film AF is the metal-containing film, the third processing gas may include at least one selected from the group consisting of a fluorine gas (F₂), a hydrogen fluoride gas (HF), a chlorine gas (Cl₂), a hydrogen chloride gas (HCl), a boron trichloride gas (BCl₃), a bromine gas (Br₂), and a hydrogen bromide gas (HBr).

FIG. 6D is a diagram illustrating an example of a cross-sectional structure of the substrate W after the execution of the step ST14a. As illustrated in FIG. 6D, in the step ST14a, the exposed portion of the antireflection film AF in the opening OP is etched. That is, in the step ST14a, the antireflection film AF may be etched using the mask film MK and/or the deposit DF as the mask. In addition, in the step ST14a, a part of the deposit DF may be etched together with the antireflection film AF. That is, in the step ST14a, the opening width of the opening OP may be widened.

### Other Examples of Step ST1

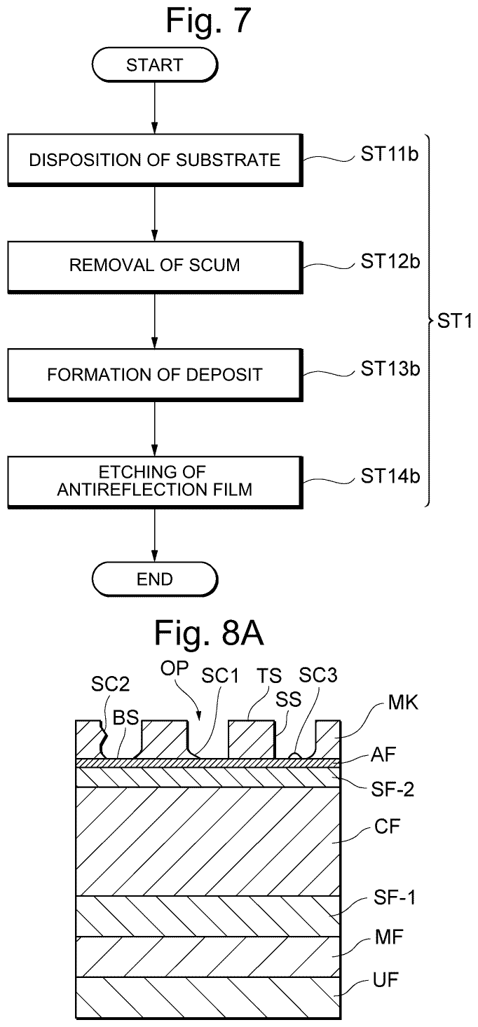

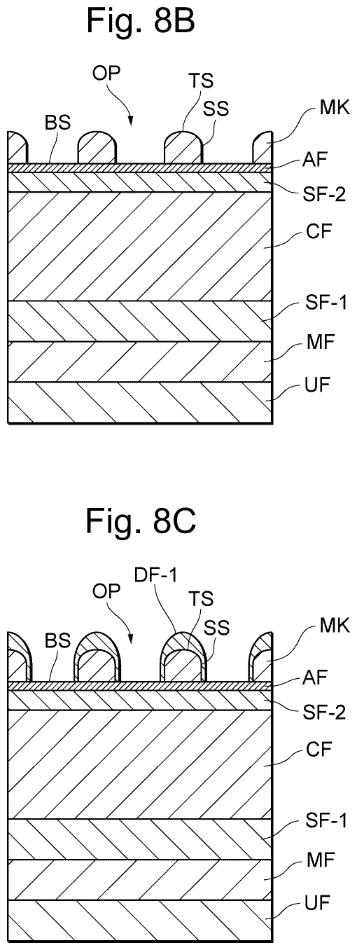

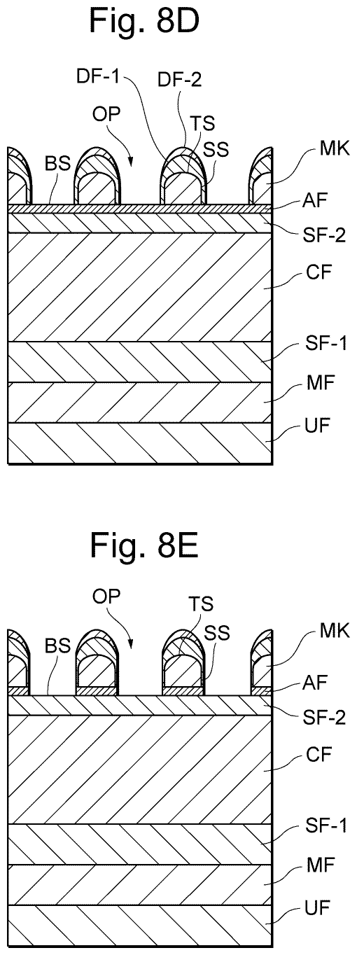

FIG. 7 is a flowchart illustrating an example of the step (ST1) of preparing the substrate. In the present example, the step ST1 includes a step (ST11b) of disposing the substrate, a step (ST12b) of removing the scum, a step (ST13b) of forming the deposit, and a step (ST14b) of etching the antireflection film. FIGS. 8A to 8D are diagrams illustrating an example of a cross-sectional structure of the substrate W in the step ST1. In each step illustrated in FIG. 7, at least one of the one or two or more gases exemplified in each step illustrated in FIG. 3 may be used.

First, in the step ST12b, the substrate W is disposed on the substrate support 11. In the step ST11b, the same substrate (see FIG. 8A) as in the step ST11a may be disposed on the substrate support 11 in the same manner as in the step ST11a. Next, in the step ST12b, the scum is removed in the same manner as in the step ST12a (see FIG. 8B).

Next, in the step ST13b, the deposit DF is formed. In the present example, the step ST13b is different from the step ST13a in that the deposit DF is formed to have a stacked structure of the deposits DF-1 and DF-2. That is, first, the deposit DF-1 is formed in the same manner as in the step ST13a. Next, in the step ST13b, the deposit DF-2 is formed on the deposit DF-1. The deposit DF-2 may have a composition different from that of the deposit DF-1. As an example, in a case where the deposit DF-1 is a deposit containing carbon, the deposit DF-2 may be a deposit containing silicon.

Next, in the step ST14b, the antireflection film AF is etched. In the step ST14b, the antireflection film AF may be etched in the same manner as in the step ST14a. That is, the antireflection film AF may be etched using the mask film MK, the deposit DF-1, and the deposit DF-2 as the masks. In addition, in the step ST14b, a part of the deposit DF-1 and/or the deposit DF-2 may be etched together with the antireflection film AF.

### Other Examples of Step ST1

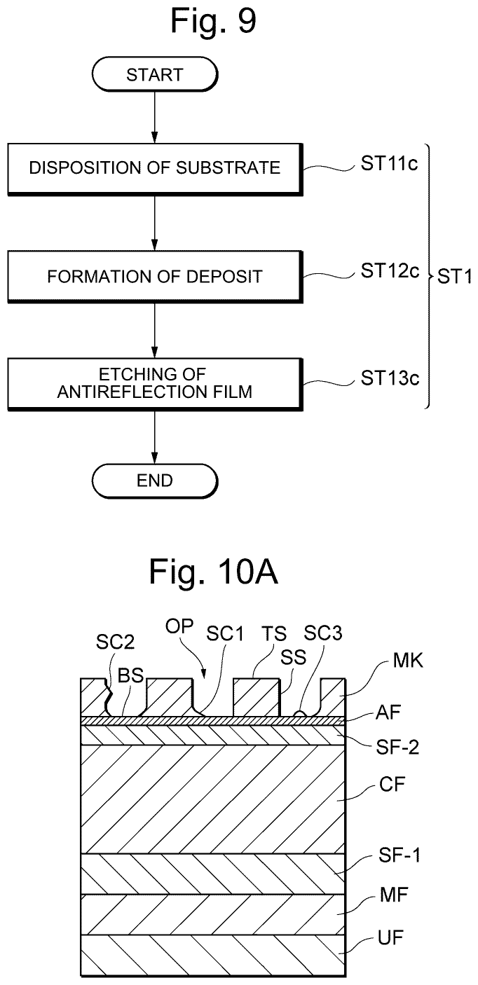

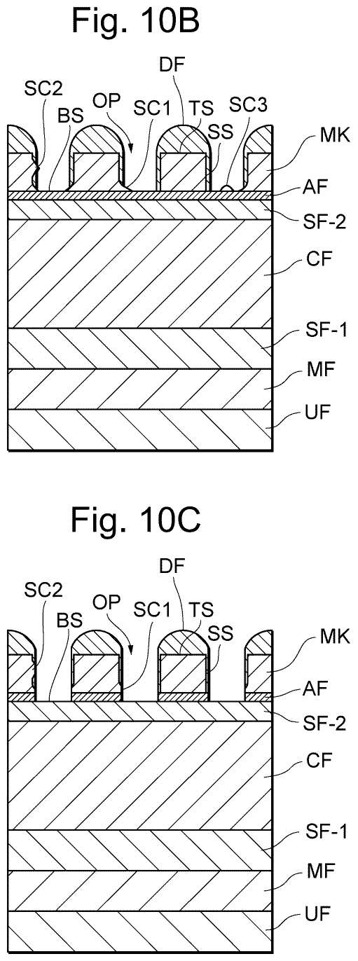

FIG. 9 is a flowchart illustrating an example of the step (ST1) of preparing the substrate. In the present example, the step ST1 includes a step (ST11c) of disposing the substrate, a step (ST12c) of forming the deposit, a step (ST13c) of removing the scum, and a step (ST14c) of etching the antireflection film. FIGS. 10A to 10C are diagrams illustrating an example of a cross-sectional structure of the substrate W in the step ST1. In each step illustrated in FIG. 9, at least one of the one or two or more gases exemplified in each step illustrated in FIG. 3 may be used.

First, in the step ST11c, the substrate W is disposed on the substrate support 11. In the step ST11c, the same substrate (see FIG. 8A) as in the step ST11a may be disposed on the substrate support 11 in the same manner as in the step ST11a.

Next, in the step ST12c, the deposit DF is formed. In the step ST12c, the deposit DF may be formed in the same manner as in the step ST13a. In an embodiment, the deposit DF may be formed to cover the scum on the mask film MK. In addition, in an embodiment, the deposit DF may be formed such that a part of the scum on the mask film MK protrudes from the deposit DF. That is, the deposit DF may be formed on the mask film MK such that a part of the scum is exposed to the opening OP.

Next, in the step ST13c, the antireflection film AF is etched. In the step ST13c, the antireflection film AF may be etched in the same manner as in the step ST14a. That is, the antireflection film AF may be etched using the mask film MK and the deposit DF as the mask. In the step ST13c, the scum and/or the deposit DF may be etched in addition to the antireflection film AF. Here, a part or all of the scum may be etched. As an example, a portion of the scum which is exposed to the opening OP from the deposit DF may be etched.

### Other Examples of Step ST23

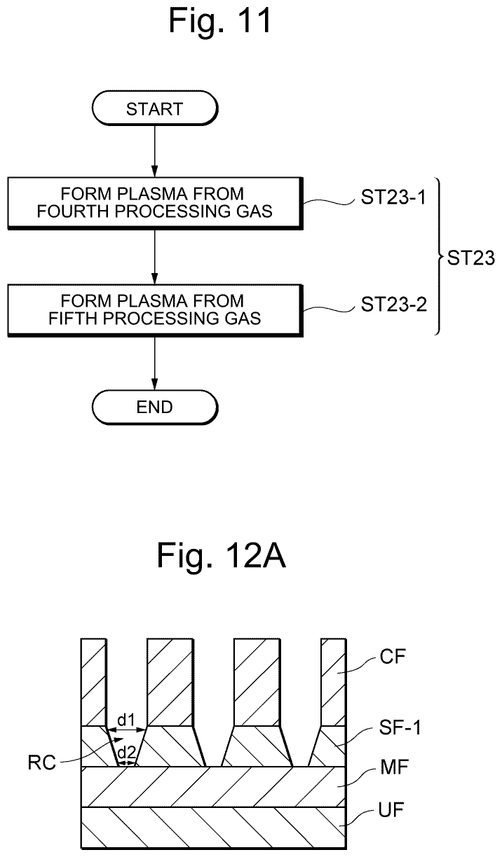

FIG. 11 is a flowchart illustrating an example of the step ST23. In an embodiment, the step ST23 includes a step (ST23-1) of forming the plasma from a fourth processing gas and a step (ST23-2) of forming plasma from a fifth processing gas. In each step illustrated in FIG. 11, at least one of the one or two or more gases exemplified in each step illustrated in FIG. 3 may be used.

In the step ST23-1, the silicon-containing film SF-1 is etched by the plasma formed from the fourth processing gas. The fourth processing gas may include a gas containing fluorine. In an embodiment, the fluorine-containing gas may be a gas that may be used in the step ST23 in FIG. 3. As an example, the fourth processing gas may include a fluorocarbon gas and/or a hydrogen fluoride gas. As an example, the fourth processing gas may further include a hydrofluorocarbon gas.

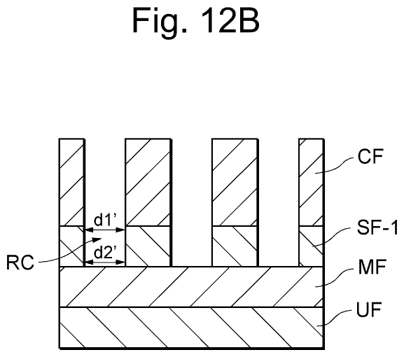

FIG. 12A is a diagram illustrating an example of a cross-sectional structure of the substrate W after the execution of the step ST23-1. In an embodiment, in the step ST23-1, the silicon-containing film SF-1 is etched, and thus the concave portion RC having a tapered shape cross section may be formed as illustrated in FIG. 11A. As an example, after the execution of the step ST23-1, in the concave portion RC, the opening width d1 on a carbon-containing film CF side is larger than the opening width d2 on a metal-containing film MF or an underlying film UF side. As an example, the opening width d1 may be an opening width of the concave portion RC at a position closer to the carbon-containing film CF than the center in the depth direction of the concave portion RC. In addition, the opening width d2 may be an opening width of the concave portion RC at a position closer to the metal-containing film MF or the underlying film UF than the center in the depth direction of the concave portion RC. In the step ST23-1, the film (the metal-containing film MF in the example of FIG. 12A) directly below the silicon-containing film SF-1 may or may not be exposed.

In the step ST23-2, the silicon-containing film SF-1 is further etched by the plasma formed from the fifth processing gas. The fifth processing gas may include a hydrogen fluoride gas and a carbon-containing gas. In an embodiment, the carbon-containing gas may include a hydrofluorocarbon gas having 3 or more carbon atoms. As an example, the carbon-containing gas may include C₄F₆. In addition, in an embodiment, the fifth processing gas may further include an oxygen-based gas. As an example, the oxygen-based gas may be O₂.

FIG. 12B is a diagram illustrating an example of a cross-sectional structure of the substrate W after the execution of the step ST23-2. In an embodiment, in the step ST23-2, the silicon-containing film SF-1 is further etched in the concave portion RC. As a result, as illustrated in FIG. 12B, the cross-sectional shape of the concave portion RC may be a gentler tapered shape than that of FIG. 12A. That is, after the execution of the step ST23-2, the angle of the side surface of the concave portion RC may be closer to perpendicular than before the execution of the step ST23-2. In an embodiment, the opening width d2 before the execution of the step ST23-2 may be changed to an opening width d2′ larger than the opening width d2 after the execution of the step ST23-2. In addition, the opening width d1 before the execution of the step ST23-2 may remain substantially the same as the opening width d1 after the execution of the step ST23-2 or may be an opening width d1′ larger than the opening width d1. In addition, the opening width d1′ may have substantially the same size as the opening width d2′.

In an embodiment, each step in FIGS. 3, 5, 7, 9, and 11 may be executed in the same chamber. In addition, in an embodiment, a part or all of each step may be executed in different chambers. In an embodiment, each step may be executed in the same chamber without breaking the vacuum. In a case where each step is executed in a plurality of chambers, each chamber may be connected through a transport chamber that is decompressed to a pressure lower than the atmospheric pressure. The substrate and the transport chamber may be configured such that the substrate can move between respective chambers.

In the present processing method, the silicon-containing film is etched by relatively reducing the power of the bias signal. That is, the energy of the hydrogen fluoride species generated from the processing gas can be suppressed to be low. As a result, the concave portion can be appropriately formed in the silicon-containing film through the mask film such as an EUV resist.

In addition, in the present processing method, in a case where the mask film MK contains a metal, the silicon-containing film SF can be etched while removing a deposit containing the metal and/or defects contained in the mask film MK. As a result, in the etching of the silicon-containing film SF, since the influence of the deposit and/or the defect can be reduced, the defect contained in the silicon-containing film SF can be reduced. The deposit may be a compound containing the metal or the like, which is generated in the step of etching another film included in the substrate W. In addition, the defect may be an etching residue of the mask film MK generated in the step of forming the opening pattern in the mask film MK.

In addition, in the present processing method, the silicon-containing film SF can be etched while removing the deposit and/or the defect, and thus the roughness of the pattern of the silicon-containing film SF can be improved.

According to the exemplary embodiment of the present disclosure, a concave portion can be appropriately formed in the etching film.

The above each embodiment is described for the purpose of description, and is not intended to limit the scope of the present disclosure. The above each embodiment may be modified in various ways without departing from the scope and the gist of the present disclosure. For example, some configuration elements in one embodiment are able to be added to other embodiments. In addition, some configuration elements in one embodiment are able to be replaced with corresponding configuration elements in another embodiment. As an example, the present disclosure may include the following forms.

### Addendum 1

A plasma processing method executed in a plasma processing apparatus, in which the plasma processing apparatus includes a chamber and a substrate support provided in the chamber, the plasma processing method including:
(a) preparing a substrate on the substrate support, the substrate including a silicon-containing film and a mask film on the silicon-containing film, the silicon-containing film being an inorganic film containing silicon, and the mask film including an opening pattern having an opening width of 30 nm or less; and
(b) forming plasma in the chamber and etching the silicon-containing film through the mask film to form a concave portion in the silicon-containing film, in which
the (b) includes
(b-1) supplying a processing gas containing hydrogen fluoride into the chamber,
(b-2) forming plasma from the processing gas in the chamber, and
(b-3) supplying a bias signal to the substrate support, the bias signal being a bias RF signal having an effective value of power of less than 2 kW or a bias DC signal including a sequence of negatively-polarized DC pulses having an effective value of a voltage of less than 2 kV.

### Addendum 2

The plasma processing method according to Addendum 1, in which
the substrate support includes a plurality of zones in a substrate support surface that supports the substrate,
the (a) includes setting a temperature of the substrate support in units of the zones, and
in the (b), the silicon-containing film is etched in a state where the temperature of the substrate support is set in units of the zones.

### Addendum 3

the substrate support includes a temperature control module configured to control a temperature of the substrate, the temperature control module including one or a plurality of heaters, and
the (b) is executed in a state where a temperature of the substrate support is set to 80° C. or less by the temperature control module.

### Addendum 4

The plasma processing method according to any one of Addenda 1 to 3, in which the processing gas further includes at least one selected from the group consisting of a carbon-containing gas, a phosphorus-containing gas, a metal-containing gas, a boron-containing gas, an oxygen-containing gas, and a halogen-containing gas.

### Addendum 5

The plasma processing method according to any one of Addenda 1 to 4, in which the processing gas includes a phosphorus-containing gas.

### Addendum 6

The plasma processing method according to any one of Addenda 1 to 5, in which the processing gas includes at least one inert gas selected from the group consisting of a noble gas and a nitrogen gas.

### Addendum 7

The plasma processing method according to Addendum 6, in which a proportion of flow rates of the hydrogen fluoride gas and the inert gas to a total flow rate of the processing gas is 50 vol % or more.

### Addendum 8

The plasma processing method according to Addendum 7, in which a ratio of the flow rate of the inert gas to the flow rate of the hydrogen fluoride gas is 0.1 or more and 200 or less.

### Addendum 9

The plasma processing method according to any one of Addenda 1 to 8, in which
the plasma processing apparatus has
a first gas injector that is disposed on an upper surface of the chamber to face the substrate support, and
a second gas injector that is disposed on a side surface of the chamber,
the processing gas includes at least one first gas that does not contain carbon and at least one second gas that contains carbon,
at least one of the first gas is supplied from the first gas injector, and
at least one of the second gas is supplied from the second gas injector.

### Addendum 10

The plasma processing method according to any one of Addenda 1 to 8, in which
the plasma processing apparatus has
a first gas injector disposed on an upper surface of the chamber in the chamber, and
a second gas injector disposed on a side surface of the chamber in the chamber,
the processing gas includes at least one of carbon-containing gas,
the at least one of carbon-containing gas is supplied into the chamber from the first gas injector and the second gas injector, and
a flow rate of the at least one of carbon-containing gas supplied into the chamber from the second gas injector is higher than a flow rate of the at least one of carbon-containing gas supplied into the chamber from the first gas injector.

### Addendum 11

The plasma processing method according to any one of Addenda 1 to 10, in which in the (b), a pressure in the chamber is set to 50 mTorr or less.

### Addendum 12

The plasma processing method according to any one of Addenda 1 to 11, in which the mask film includes a resist film.

### Addendum 13

The plasma processing method according to any one of Addenda 1 to 12, in which the mask film includes an EUV resist film.

### Addendum 14

The plasma processing method according to Addendum 12, in which the resist film includes a metal-containing resist.

### Addendum 15

The plasma processing method according to any one of Addenda 1 to 14, in which a thickness of the silicon-containing film is 40 nm or less.

### Addendum 16

The plasma processing method according to Addendum 14, in which an aspect ratio of the concave portion formed in the silicon-containing film is 5 or less.

### Addendum 17

The plasma processing method according to any one of Addenda 1 to 16, in which the (a) includes
(a-1) preparing a substrate including the silicon-containing film, an antireflection film on the silicon-containing film, and the mask film on the antireflection film, and
(a-2) removing a portion of the antireflection film exposed from the opening pattern and a part of the mask film using plasma formed from a first processing gas containing oxygen.

### Addendum 18

The plasma processing method according to Addendum 17, further including: (a-3) forming, after the (a-2), at least one of a deposit selected from the group consisting of carbon, silicon, and a metal on a first region and a second region of the mask film by using a second processing gas, the first region including an upper surface of the mask film, the second region including a side surface of the mask film, and the side surface defining the opening pattern; and
(a-4) removing at least a part of the deposit on the second region and a portion of the antireflection film exposed from the opening pattern by using plasma formed from a third processing gas containing oxygen.

### Addendum 19

The plasma processing method according to any one of Addenda 1 to 18, in which the (a) includes
(a-1) preparing a substrate including the silicon-containing film, an antireflection film on the silicon-containing film, and a mask film on the antireflection film,
(a-3) forming, after the (a-1), at least one of a deposit selected from the group consisting of carbon, silicon, and a metal on a first region and a second region of the mask film by using a second processing gas, the first region including an upper surface of the mask film, the second region including a side surface of the mask film, and the side surface defining the opening pattern, and
(a-4) removing at least a part of the deposit on the second region and a portion of the antireflection film exposed from the opening pattern by using a third processing gas.

### Addendum 20

A plasma processing method executed in a plasma processing apparatus, in which the plasma processing apparatus includes a chamber and a substrate support provided in the chamber, the plasma processing method including:
(a) preparing a substrate on the substrate support, the substrate including a silicon-containing film and a mask film on the silicon-containing film, the silicon-containing film being an inorganic film containing silicon, and the mask film including an opening pattern; and
(b) forming plasma in the chamber and etching the silicon-containing film to form the opening pattern in the silicon-containing film, in which
in the (a), a width of an opening included in the opening pattern is 30 nm or less, and
the (b) includes
(b-1) supplying a processing gas containing at least hydrogen and fluorine into the chamber,
(b-2) forming plasma including a hydrogen fluoride species from the processing gas in the chamber, and
(b-3) supplying a bias signal to the substrate support, the bias signal being a bias RF signal having an effective value of power of 2 kW or a bias DC signal including a sequence of negatively-polarized DC pulses having an effective value of a voltage of less than 2 kV.

### Addendum 21

A plasma processing method executed in a plasma processing apparatus, in which the plasma processing apparatus includes a chamber and a substrate support provided in the chamber, the plasma processing method including:
(a) preparing a substrate, the substrate including a first silicon-containing film, a carbon-containing film on the first silicon-containing film, a second silicon-containing film on the carbon-containing film, and a resist film on the second silicon-containing film, and the resist film including an opening pattern having an opening width of 30 nm or less;
(b) etching the second silicon-containing film through the resist film and forming a first concave portion on the second silicon-containing film;
(c) etching the carbon-containing film through the first concave portion and forming a second concave portion on the carbon-containing film; and
(d) etching the first silicon-containing film through the second concave portion, in which
in the (b), (c), and (d), a bias signal having an effective value of less than 2 kW is supplied to the substrate support, and
the (b) includes
(b-1) supplying a processing gas containing at least hydrogen and fluorine, and
(b-2) forming plasma containing a hydrogen fluoride species from the processing gas.

### Addendum 22

The plasma processing method according to Addendum 21, in which
the substrate further includes an underlying film under the first silicon-containing film,
the (d) includes
(d-1) etching the first silicon-containing film by using plasma formed from a fourth processing gas containing fluorine and forming a third concave portion on the first silicon-containing film, the third concave portion having an opening dimension on a carbon-containing film side larger than an opening dimension on an underlying film side, and
(d-2) enlarging the opening dimension of the third concave portion on the underlying film side by using plasma formed from a fifth processing gas containing a hydrogen fluoride gas and a carbon-containing gas.

### Addendum 23

The plasma processing method according to Addendum 22, in which
the fourth processing gas includes at least one of a hydrogen fluoride gas and a fluorocarbon gas, and
the carbon-containing gas includes a hydrofluorocarbon gas having 3 or more carbon atoms.

### Addendum 24

The plasma processing method according to Addendum 22 or 23, in which plasma is continuously formed over two or more consecutive of the (b), (c), and (d).

### Addendum 25

The plasma processing method according to any one of Addenda 22 to 24, in which
the plasma processing apparatus is an inductively coupled plasma processing apparatus, and
the (a), (b), (c), and (d) are executed in the same chamber.

### Addendum 26

A plasma processing apparatus including:
a chamber;
a gas supply;
a plasma generator;
a substrate support provided in the chamber; and
a controller, in which
the controller is configured to execute
(a) preparing a substrate on the substrate support, the substrate including a silicon-containing film and a mask film on the silicon-containing film, the silicon-containing film being an inorganic film containing silicon, and the mask film including an opening pattern; and
(b) forming plasma in the chamber and etching the silicon-containing film through the mask film to form a concave portion in the silicon-containing film, in which
in the (b), the controller is configured to execute
(b-1) supplying a processing gas containing hydrogen fluoride into the chamber,
(b-2) forming plasma from the processing gas in the chamber, and
(b-3) supplying a bias signal to the substrate support, the bias signal being a bias RF signal having an effective value of power of less than 2 kW or a bias DC signal including a sequence of negatively-polarized DC pulses having an effective value of a voltage of less than 2 kV.

What is claimed is:

1. A plasma processing method executed in a plasma processing apparatus, in which the plasma processing apparatus includes a chamber and a substrate support provided in the chamber, the plasma processing method comprising:
(a) preparing a substrate on the substrate support, the substrate including a silicon-containing film and a mask film on the silicon-containing film, the silicon-containing film being an inorganic film containing silicon, and the mask film including an opening pattern having an opening width of 30 nm or less; and
(b) forming plasma in the chamber and etching the silicon-containing film through the mask film to form a concave portion in the silicon-containing film, wherein
the (b) includes
(b-1) supplying a processing gas containing hydrogen fluoride into the chamber,
(b-2) forming plasma from the processing gas in the chamber, and
(b-3) supplying a bias signal to the substrate support, the bias signal being a bias RF signal having an effective value of power of less than 2 kW or a bias DC signal including a sequence of negatively-polarized DC pulses having an effective value of a voltage of less than 2 kV.

2. The plasma processing method according to claim 1, wherein
the substrate support includes a plurality of zones in a substrate support surface that supports the substrate,
the (a) includes setting a temperature of the substrate support in units of the zones, and
in the (b), the silicon-containing film is etched in a state where the temperature of the substrate support is set in units of the zones.

3. The plasma processing method according to claim 1, wherein
the substrate support includes a temperature control module configured to control a temperature of the substrate, the temperature control module including one or a plurality of heaters, and
the (b) is executed in a state where a temperature of the substrate support is set to 80° C. or less by the temperature control module.

4. The plasma processing method according to claim 1, wherein the processing gas further includes at least one selected from the group consisting of a carbon-containing gas, a phosphorus-containing gas, a metal-containing gas, a boron-containing gas, an oxygen-containing gas, and a halogen-containing gas.

5. The plasma processing method according to claim 1, wherein the processing gas includes a phosphorus-containing gas.

6. The plasma processing method according to claim 1, wherein the processing gas includes at least one inert gas selected from the group consisting of a noble gas and a nitrogen gas.

7. The plasma processing method according to claim 6, wherein a proportion of flow rates of the hydrogen fluoride gas and the inert gas to a total flow rate of the processing gas is 50 vol % or more.

8. The plasma processing method according to claim 7, wherein a ratio of the flow rate of the inert gas to the flow rate of the hydrogen fluoride gas is 0.1 or more and 200 or less.

9. The plasma processing method according to claim 1, wherein
the plasma processing apparatus has
a first gas injector that is disposed on an upper surface of the chamber to face the substrate support, and
a second gas injector that is disposed on a side surface of the chamber,
the processing gas includes at least one first gas that does not contain carbon and at least one second gas that contains carbon,
at least one of the first gas is supplied from the first gas injector, and
at least one of the second gas is supplied from the second gas injector.

10. The plasma processing method according to claim 1, wherein
the plasma processing apparatus has
a first gas injector disposed on an upper surface of the chamber in the chamber, and
a second gas injector disposed on a side surface of the chamber in the chamber,
the processing gas includes at least one of carbon-containing gas,
the at least one of carbon-containing gas is supplied into the chamber from the first gas injector and the second gas injector, and
a flow rate of the at least one of carbon-containing gas supplied into the chamber from the second gas injector is higher than a flow rate of the at least one of carbon-containing gas supplied into the chamber from the first gas injector.

11. The plasma processing method according to claim 1, wherein in the (b), a pressure in the chamber is set to 50 mTorr or less.

12. The plasma processing method according to claim 1, wherein the mask film includes a resist film.

13. The plasma processing method according to claim 1, wherein the mask film includes an EUV resist film.

14. The plasma processing method according to claim 12, wherein the resist film includes a metal-containing resist.

15. The plasma processing method according to claim 1, wherein a thickness of the silicon-containing film is 40 nm or less.

16. The plasma processing method according to claim 14, wherein an aspect ratio of the concave portion formed in the silicon-containing film is 5 or less.

17. The plasma processing method according to claim 1, wherein the (a) includes
(a-1) preparing a substrate including the silicon-containing film, an antireflection film on the silicon-containing film, and the mask film on the antireflection film, and
(a-2) removing a portion of the antireflection film exposed from the opening pattern and a part of the mask film using plasma formed from a first processing gas containing oxygen.

18. The plasma processing method according to claim 17, further comprising:
(a-3) forming, after the (a-2), at least one of a deposit selected from the group consisting of carbon, silicon, and a metal on a first region and a second region of the mask film by using a second processing gas, the first region including an upper surface of the mask film, the second region including a side surface of the mask film, and the side surface defining the opening pattern; and
(a-4) removing at least a part of the deposit on the second region and a portion of the antireflection film exposed from the opening pattern by using plasma formed from a third processing gas containing oxygen.

19. The plasma processing method according to claim 1, wherein the (a) includes
(a-1) preparing a substrate including the silicon-containing film, an antireflection film on the silicon-containing film, and a mask film on the antireflection film,
(a-3) forming, after the (a-1), at least one of a deposit selected from the group consisting of carbon, silicon, and a metal on a first region and a second region of the mask film by using a second processing gas, the first region including an upper surface of the mask film, the second region including a side surface of the mask film, and the side surface defining the opening pattern, and
(a-4) removing at least a part of the deposit on the second region and a portion of the antireflection film exposed from the opening pattern by using a third processing gas.

20. A plasma processing method executed in a plasma processing apparatus, in which the plasma processing apparatus includes a chamber and a substrate support provided in the chamber, the plasma processing method comprising:
(a) preparing a substrate on the substrate support, the substrate including a silicon-containing film and a mask film on the silicon-containing film, the silicon-containing film being an inorganic film containing silicon, and the mask film including an opening pattern; and
(b) forming plasma in the chamber and etching the silicon-containing film through the mask film to form a concave portion in the silicon-containing film, wherein
in the (a), a width of an opening included in the opening pattern is 30 nm or less, and
the (b) includes
(b-1) supplying a processing gas containing at least hydrogen and fluorine into the chamber,
(b-2) forming plasma including a hydrogen fluoride species from the processing gas in the chamber, and
(b-3) supplying a bias signal to the substrate support, the bias signal being a bias RF signal having an effective value of power of 2 kW or a bias DC signal including a sequence of negatively-polarized DC pulses having an effective value of a voltage of less than 2 kV.

21. A plasma processing method executed in a plasma processing apparatus, in which the plasma processing apparatus includes a chamber and a substrate support provided in the chamber, the plasma processing method comprising:
(a) preparing a substrate, the substrate including a first silicon-containing film, a carbon-containing film on the first silicon-containing film, a second silicon-containing film on the carbon-containing film, and a resist film on the second silicon-containing film, and the resist film including an opening pattern having an opening width of 30 nm or less;
(b) etching the second silicon-containing film through the resist film and forming a first concave portion on the second silicon-containing film;
(c) etching the carbon-containing film through the first concave portion and forming a second concave portion on the carbon-containing film; and
(d) etching the first silicon-containing film through the second concave portion, wherein
in the (b), (c), and (d), a bias signal having an effective value of less than 2 kW is supplied to the substrate support, and
the (b) includes
(b-1) supplying a processing gas containing at least hydrogen and fluorine, and
(b-2) forming plasma containing a hydrogen fluoride species from the processing gas.

22. The plasma processing method according to claim 21, wherein
the substrate further includes an underlying film under the first silicon-containing film,
the (d) includes
(d-1) etching the first silicon-containing film by using plasma formed from a fourth processing gas containing fluorine and forming a third concave portion on the first silicon-containing film, the third concave portion having an opening dimension on a carbon-containing film side larger than an opening dimension on an underlying film side, and
(d-2) enlarging the opening dimension of the third concave portion on the underlying film side by using plasma formed from a fifth processing gas containing a hydrogen fluoride gas and a carbon-containing gas.

23. The plasma processing method according to claim 22, wherein
the fourth processing gas includes at least one of a hydrogen fluoride gas and a fluorocarbon gas, and
the carbon-containing gas includes a hydrofluorocarbon gas having 3 or more carbon atoms.

24. The plasma processing method according to claim 22, wherein plasma is continuously formed over two or more consecutive of the (b), (c), and (d).

25. The plasma processing method according to claim 22, wherein
the plasma processing apparatus is an inductively coupled plasma processing apparatus, and
the (a), (b), (c), and (d) are executed in the same chamber.

26. A plasma processing apparatus comprising:
a chamber;
a gas supply;
a plasma generator;
a substrate support provided in the chamber; and
a controller, wherein
the controller is configured to cause
(a) preparing a substrate on the substrate support, the substrate including a silicon-containing film and a mask film on the silicon-containing film, the silicon-containing film being an inorganic film containing silicon, and the mask film including an opening pattern having an opening width of 30 nm or less, and
(b) forming plasma in the chamber and etching the silicon-containing film through the mask film to form a concave portion in the silicon-containing film, in which in the (b), the controller is configured to execute
(b-1) supplying a processing gas containing hydrogen fluoride into the chamber,
(b-2) forming plasma from the processing gas in the chamber, and
(b-3) supplying a bias signal to the substrate support, the bias signal being a bias RF signal having an effective value of power of less than 2 kW or a bias DC signal including a sequence of negatively-polarized DC pulses having an effective value of a voltage of less than 2 kV.
